(19) United States
(12) Patent Application Publication
(10) Pub. No.: US 2025/0133790 A1
(43) Pub. Date: Apr. 24, 2025

(54) SEMICONDUCTOR DEVICE AND METHOD FOR FABRICATING THE SAME

(71) Applicant: United Semiconductor (Xiamen) Co., Ltd., Xiamen (CN)

(72) Inventors: Yong XIE, Shamen City (CN); Shih-Hsien HUANG, Kaohsiung City (TW); Sheng-Hsu LIU, Changhua County (TW); Qiang GAO, Shamen City (CN); Wen Yi TAN, Xiamen (CN)

(73) Assignee: United Semiconductor (Xiamen) Co., Ltd., Xiamen (CN)

(21) Appl. No.: 18/395,709

(22) Filed: Dec. 25, 2023

(30) Foreign Application Priority Data
Oct. 19, 2023 (CN) 202311356601.1

(51) Int. Cl. H01L 29/06; H01L 21/02; H01L 21/768; H01L 29/04; H01L 29/66

(52) U.S. Cl. CPC H10D 62/124; H01L 21/0262; H01L 21/76829; H10D 62/405; H10D 64/018

(57) ABSTRACT

A semiconductor device includes a gate structure, a first epitaxial layer, a second epitaxial layer and a cap layer. The gate structure is disposed on a substrate. The first epitaxial layer is disposed in the substrate and at two sides of the gate structure. The second epitaxial layer is disposed on the first epitaxial layer, in which an included angle between a surface of the second epitaxial layer and a horizontal direction is 15 degrees to 35 degrees. The cap layer is disposed on the second epitaxial layer.

### BACKGROUND OF THE INVENTION

### 1. Field of the Invention

The present disclosure relates to the field of semiconductor devices, and more particularly, to a semiconductor device including an epitaxial layer which has a surface with a specific inclined angle and a method for fabricating the same.

### 2. Description of the Prior Art

As the line width of semiconductor process continues to shrink, more challenges and bottlenecks have emerged in the semiconductor process. Take a metal oxide semiconductor (MOS) transistor with a cap layer formed on an epitaxial layer as an example, when the cap layer has a thicker thickness, short circuits are likely to occur between adjacent devices; when the cap layer has a thinner thickness, voids may be formed on the outer surface of the epitaxial layer due to a portion of the epitaxial layer being removed during the cleaning process. As a result, when performing the subsequent self-aligned silicide process, the silicide tends to flow along the voids of the epitaxial layer, which causes the silicide to form at unexpected positions.

Therefore, how to improve the structure of semiconductor device and method for fabricating the same, so as to reduce the probability of short circuits between devices and reduce the probability of unexpected flow of silicide, has become an important issue for the relevant industry.

### SUMMARY OF THE INVENTION

According to one aspect of the present disclosure, a semiconductor device includes a gate structure, a first epitaxial layer, a second epitaxial layer and a cap layer. The gate structure is disposed on a substrate. The first epitaxial layer is disposed in the substrate and at two sides of the gate structure. The second epitaxial layer is disposed on the first epitaxial layer, in which an included angle between a surface of the second epitaxial layer and a horizontal direction is 15 degrees to 35 degrees. The cap layer is disposed on the second epitaxial layer.

According to another aspect of the present disclosure, a method for fabricating a semiconductor device includes steps as follows. A gate structure is formed on a substrate. Two recesses are formed in the substrate and at two sides of the gate structure. A first epitaxial layer is formed in the two recesses. A second epitaxial layer is formed on the first epitaxial layer, in which an included angle between a surface of the second epitaxial layer and a horizontal direction is 15 degrees to 35 degrees. A cap layer is formed on the second epitaxial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 are schematic cross-sectional views showing steps of a method for fabricating a semiconductor device according to an embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

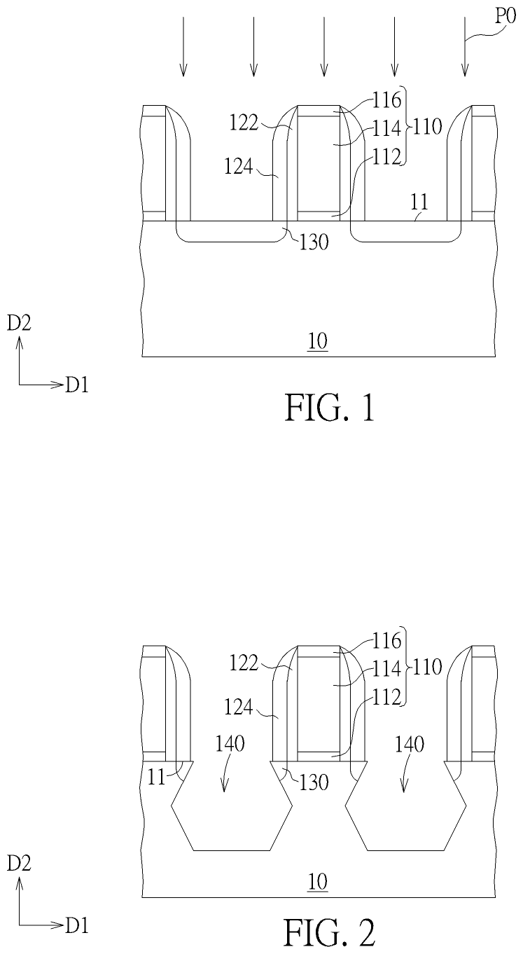

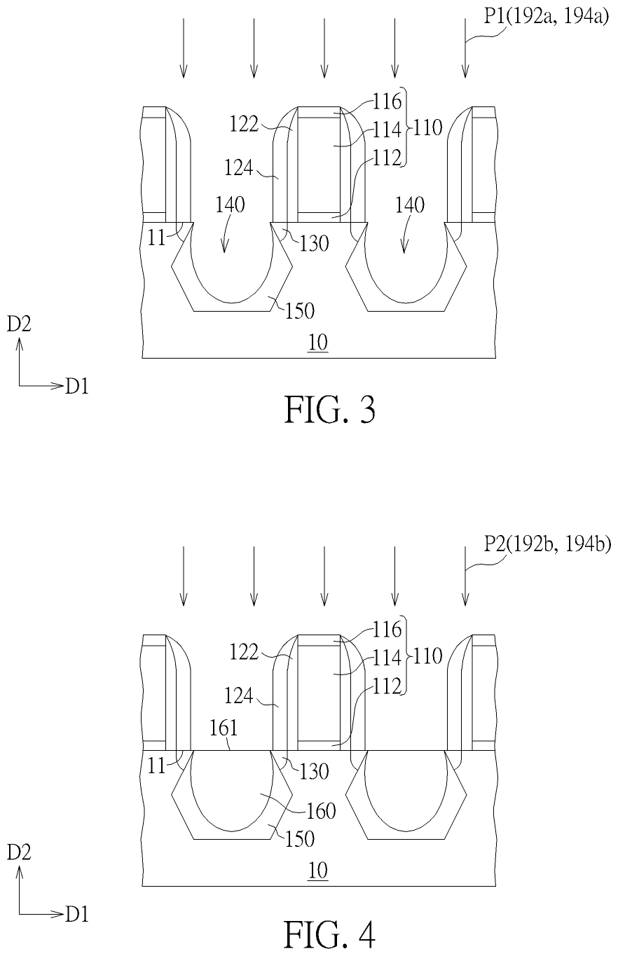

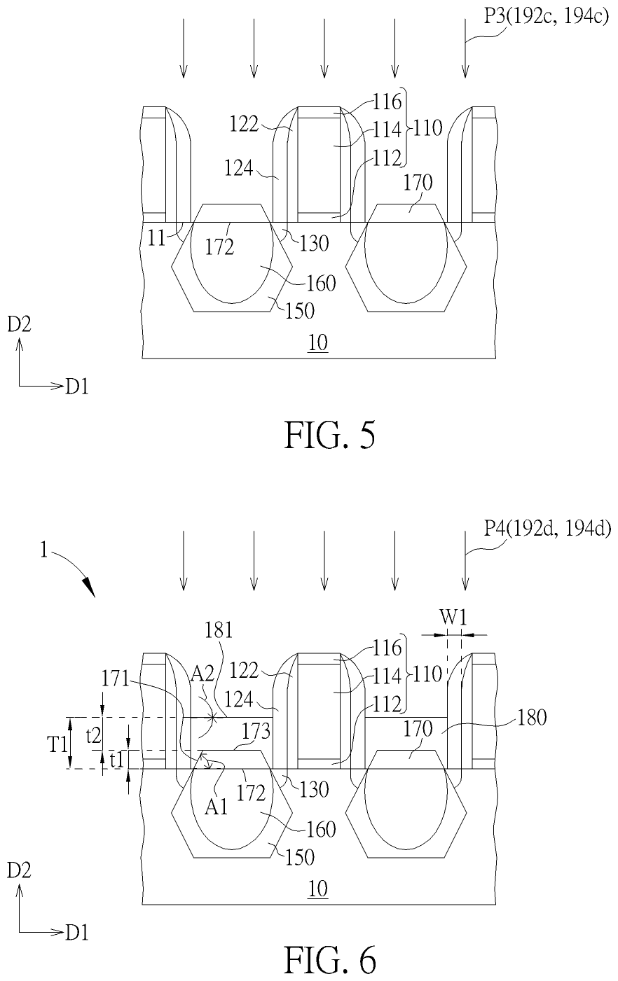

Please refer to FIG. 1 to FIG. 6, which are schematic cross-sectional views showing steps of a method for fabricating a semiconductor device according to an embodiment of the present disclosure. In the embodiment, the semiconductor device 1 (see FIG. 6) is exemplary a PMOS transistor for explanation. As shown in FIG. 1, a gate structure 110 is firstly formed on a substrate 10. The substrate 10 may be a silicon substrate, an epitaxial silicon substrate, a silicon carbide substrate or a silicon on insulator (SOI) substrate. The substrate 10 may include a well region (not shown). For example, the well region may be formed by an ion implantation process (not shown). The dopant of the well region may be adjusted depending on the subsequently formed semiconductor device 1 being applied to an NMOS transistor or a PMOS transistor. In the embodiment, the semiconductor device 1 is exemplary a PMOS transistor. Therefore, the well region is an N-type well region, and the well region may be doped with N-type dopants, such as arsenic, phosphorus, etc.

The gate structure 110 includes a gate dielectric layer 112, a gate material layer 114 and a mask layer 116 in sequence from bottom to top. In the embodiment, the formation of the gate structure 110 may be accomplished by a gate first process, a high-k first approach of a gate last process, or a high-k last approach of a gate last process. In the embodiment, the gate structure 110 is exemplary formed by a high-k last approach. A gate dielectric material, a gate material and a mask material may be formed sequentially on the substrate 10 by a deposition process, and a pattern transfer process may be performed by using a patterned photoresist (not shown) as mask to remove a portion of the mask material, a portion of the gate material and a portion of the gate dielectric material by a single etching process or multiple etching processes. Next, the patterned photoresist is removed, and the gate structure 110 including the gate dielectric layer 112, the gate material layer 114 and the mask layer 116 is formed on a top surface 11 of the substrate 10. The material of the gate dielectric layer 112 may include, but is not limited to, oxides and/or nitrides. The oxide, for example, may include silicon dioxide (SiO₂). The nitride, for example, may include silicon nitride (SiN). The material of the gate material layer 114 may include, but is not limited to, non-metallic conductive materials, such as polycrystalline silicon. The material of the mask layer 116 may include, but is not limited to, silicon dioxide (SiO₂), silicon nitride (SiN), silicon carbide (SiC) and/or silicon oxynitride (SiON).

In addition, although the embodiment takes a planar transistor as an example, in other modified embodiments, the method for fabricating the semiconductor device of the present disclosure may also be applied to a non-planar transistor, such as a transistor with a fin-shaped structure. In this case, the portion of the substrate 10 shown in FIG. 1 may represent the fin-shaped structure formed on the substrate 10.

Next, a first spacer 122 may be optionally formed to surround the gate structure 110. The first spacer 122 may be, for example, an offset spacer. The material of the first spacer 122 may include, for example, oxides such as silicon dioxide (SiO₂). Next, an ion implantation process P0 is performed to form two lightly doped drain regions 130 in the substrate 10 and at two sides of the gate structure 110. The conductivity types of the two lightly doped drain regions 130 are identical to each other, and are different from the conductivity type of the well region. In the embodiment, the well region is an N-type well region, and the conductivity types of the two lightly doped drain regions 130 are P-type. Therefore, in the ion implantation process P0, P-type dopants are implanted into the substrate 10. The P-type dopants may include, for example, boron (B), aluminum (Al), gallium (Ga), or indium (In). Next, a second spacer 124 is formed to surround the gate structure 110. The material of the second spacer 124 may include nitrides, such as silicon nitride, silicon oxynitride or silicon carbonitride.

Next, as shown in FIG. 2, two recesses 140 are formed in the substrate 10 and at the two sides of the gate structure 110. For example, a dry etching process and/or a wet etching process may be performed, in which the gate structure 110, the first spacer 122 and the second spacer 124 are served as etching masks, and a single etching process or multiple etching processes are performed to remove a portion of the substrate 10 to form the two recesses 140 in the substrate 10 and at the two sides of the gate structure 110.

Next, as shown in FIG. 3, a buffer layer 150 may be optionally formed in the two recesses 140. Specifically, a selective epitaxial growth process P1 may be performed. For example, a chemical vapor deposition system (not shown) may be used, and an etching gas 192a and a deposition material gas 194a are respectively introduced into the chemical vapor deposition system to form the buffer layer 150 in the two recesses 140. According to an embodiment, the material of the buffer layer 150 includes silicon germanium (SiGe), the etching gas 192a includes hydrogen chloride (HCl), and the deposition material gas 194a includes a silicon (Si) source gas, such as dichlorosilane (DCS). The deposition material gas 194a may further include other deposition material gases (not labeled), such as germanium (Ge) source gas, but not limited thereto. The types of the etching gas 192a and the deposition material gas 194a may be adjusted according to the composition of the buffer layer 150.

Next, as shown in FIG. 4, a first epitaxial layer 160 is formed in the two recesses 140, in which the first epitaxial layer 160 is disposed on the buffer layer 150. Specifically, a selective epitaxial growth process P2 may be performed. For example, a chemical vapor deposition system (not shown) may be used, and an etching gas 192b and a deposition material gas 194b are respectively introduced into the chemical vapor deposition system to form the first epitaxial layer 160 in the two recesses 140. According to an embodiment, the material of the first epitaxial layer 160 includes silicon germanium, the material of the buffer layer 150 includes silicon germanium, and a concentration of germanium in the first epitaxial layer 160 is greater than a concentration of germanium in the buffer layer 150. The etching gas 192b includes hydrogen chloride, and the deposition material gas 194b includes a silicon source such gas, as dichlorosilane. The deposition material gas 194b may further include other deposition material gases (not labeled), such as germanium source gas, but not limited thereto. The types of the etching gas 192b and the deposition material gas 194b may be adjusted according to the composition of the first epitaxial layer 160.

In FIG. 4, the buffer layer 150 is disposed between the substrate 10 and the first epitaxial layer 160, so that the first epitaxial layer 160 does not contact the substrate 10 directly. With the buffer layer 150, the stress between the substrate 10 and the first epitaxial layer 160 can be reduced. The top surface 161 of the first epitaxial layer 160 is aligned or substantially aligned with the top surface 11 of the substrate 10. In other words, the first epitaxial layer 160 does not protrude from or substantially does not protrude from the top surface 11 of the substrate 10. Herein, the top surface 11 of substrate 10 refers to the surface of substrate 10 on which no recesses 140 are formed.

Next, as shown in FIG. 5, a second epitaxial layer 170 is formed on the first epitaxial layer 160. Specifically, a selective epitaxial growth process P3 may be performed. For example, a chemical vapor deposition system (not shown) may be used, and an etching gas 192c and a deposition material gas 194c may be respectively introduced into the chemical vapor deposition system to form the second epitaxial layer 170 on the first epitaxial layer 160. According to an embodiment, the material of the second epitaxial layer 170 includes silicon germanium, the etching gas 192c includes hydrogen chloride, and the deposition material gas 194c includes a silicon source gas, such as dichlorosilane. The deposition material gas 194c may further include other deposition material gases (not labeled), such as a germanium source gas, but not limited thereto. The types of the etching gas 192c and the deposition material gas 194c may be adjusted according to the composition of the second epitaxial layer 170. In FIG. 5, the bottom surface 172 of the second epitaxial layer 170 is aligned or substantially aligned with the top surface 11 of the substrate 10. In other words, the second epitaxial layer 170 protrudes from or substantially protrudes from the top surface 11 of the substrate 10, and the second epitaxial layer 170 has a trapezoidal cross-section.

When the materials of the buffer layer 150, the first epitaxial layer 160, and the second epitaxial layer 170 all include silicon germanium, the concentration of germanium in the buffer layer 150 is lower than the concentration of germanium in the first epitaxial layer 160, and the concentration of germanium in the second epitaxial layer 170 changes in gradient along the vertical direction D2 from bottom to top. For example, the concentration of germanium in the second epitaxial layer 170 may decrease gradually from bottom to top along the vertical direction D2, or may change gradually from a concentration identical to the concentration of germanium in the first epitaxial layer 160 to zero from bottom to top along the vertical direction D2.

Next, as shown in FIG. 6, a cap layer 180 is formed on the second epitaxial layer 170. The cap layer 180 completely covers the second epitaxial layer 170. Specifically, a selective epitaxial growth process P4 may be performed. For example, a chemical vapor deposition system (not shown) may be used, and an etching gas 192d and a deposition material gas 194d may be respectively introduced into the chemical vapor deposition system to form the cap layer 180 on the second epitaxial layer 170. According to an embodiment, the material of the cap layer 180 includes silicon, and the material of the cap layer 180 does not include germanium (that is, the concentration of germanium in the cap layer 180 is zero). The etching gas 192d includes hydrogen chloride, and the deposition material gas 194d includes a silicon source gas, such as dichlorosilane, but not limited thereto. The types of the etching gas 192d and the deposition material gas 194d may be adjusted according to the composition of the cap layer 180. Thereby, the fabrication of the semiconductor device 1 is completed.

A molar ratio of the etching gas 192c to the deposition material gas 194c for forming the second epitaxial layer 170 may be greater than a molar ratio of the etching gas 192d to the deposition material gas 194d for forming the cap layer 180. Thereby, it is beneficial to allow the included angle A1 between the surface 171 of the second epitaxial layer 170 and the horizontal direction D1 and the included angle A2 between the surface 181 of the cap layer 180 and the horizontal direction D1 to fall within a specific range, or to allow the surface 171 and the surface 181 to have a specific crystal orientation, so that it is beneficial to reduce the probability of short circuits between devices and reduce the probability of unexpected flow of silicide. For example, the molar ratio of the etching gas 192c to the deposition material gas 194c for forming the second epitaxial layer 170 may be 1 to 2. The molar ratio of the etching gas 192d to the deposition material gas 194d for forming the cap layer 180 may be 0.45 to 0.55.

According to the present disclosure, when forming the first epitaxial layer 160, an in-situ implantation process and an annealing process may be performed to implant dopants into the first epitaxial layer 160 to form source/drain regions (not labeled). Alternatively, after the first epitaxial layer 160 is formed, the implantation process and the annealing process are performed to form the source/drain regions in the first epitaxial layer 160. The above two methods to form the source/drain regions are all within the scope of the present disclosure.

Although not shown in the drawings, the method for fabricating the semiconductor device may further include other processes for fabricating transistors. For example, a contact etch stop layer (CESL) and an interlayer dielectric (ILD) layer may be formed in sequence to cover the gate structure 110 and the cap layer 180. A replacement metal gate (RMG) process may be performed to replace the non-metallic conductive material of the gate structure 110 with a single-layer structure or a multi-layer structure including a metallic conductive material. The aforementioned single-layer structure may only include a low-resistance metal layer, and a material of the low-resistance metal layer may include, for example, copper (Cu), aluminum (Al), tungsten (W), titanium aluminum alloy (TiAl), cobalt tungsten phosphide (CoWP) or a combination thereof. The aforementioned multi-layer structure may be formed by a low-resistance metal layer and a high dielectric constant (high-k) dielectric layer and/or a barrier layer and/or a work function metal layer. The replacement metal gate process is well known in the art and is omitted herein.

The aforementioned film layers, such as the gate dielectric layer 112, the gate material layer 114, the mask layer 116, the first spacer 122 and the second spacer 124, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 6, which shows a schematic cross-sectional view of the semiconductor device 1 according to an embodiment of the present disclosure. Herein, the semiconductor device 1 is exemplary a PMOS transistor.

The semiconductor device 1 includes the gate structure 110, the first epitaxial layer 160, the second epitaxial layer 170 and the cap layer 180. The gate structure 110 is disposed on the substrate 10. The first epitaxial layer 160 is disposed in the substrate 10 and at two sides of the gate structure 110. The second epitaxial layer 170 is disposed on the first epitaxial layer 160. The cap layer 180 is disposed on the second epitaxial layer 170.

The semiconductor device 1 may further include the buffer layer 150, the first spacer 122 and the second spacer 124. The buffer layer 150 is disposed in the substrate 10 and at the two sides of the gate structure 110. The first spacer 122 surrounds the gate structure 110, and the second spacer 124 surrounds the first spacer 122. The gate structure 110 includes the gate dielectric layer 112, the gate material layer 114 and the mask layer 116 from bottom to top.

The included angle A1 between the surface 171 of the second epitaxial layer 170 and the horizontal direction D1 is 15 degrees to 35 degrees. The material of the second epitaxial layer 170 may include silicon germanium, and a crystal orientation of the surface 171 of the second epitaxial layer 170 may be (311). The thickness t1 of the second epitaxial layer 170 in a direction perpendicular to the horizontal direction D1 (i.e., the vertical direction D2) is 30 angstroms to 150 angstroms. Thereby, it is beneficial to reduce the probability of forming voids on the side surfaces of the second epitaxial layer 170 during the cleaning process. The aforementioned range of the thickness t1 may refer to a distance between the bottommost surface (i.e., the bottom surface 172) and the topmost surface (i.e., the top surface 173) of the second epitaxial layer 170 in the vertical direction D2. The second epitaxial layer 170 completely covers the first epitaxial layer 160. The bottom surface 172 of the second epitaxial layer 170 is aligned with or substantially aligned with the top surface 11 of the substrate 10. The second epitaxial layer 170 protrudes from or substantially protrudes from the top surface 11 of the substrate 10. The second epitaxial layer 170 has a trapezoidal cross-section.

An included angle A2 between the surface 181 of the cap layer 180 and the horizontal direction D1 is 0 degrees to 5 degrees. A material of the cap layer 180 may include silicon, and a crystal orientation of the surface 181 of the cap layer 180 may be (100). The thickness t2 of the cap layer 180 in a direction perpendicular to the horizontal direction D1 (i.e., the vertical direction D2) is 100 angstroms to 200 angstroms. The thickness t2 of the cap layer 180 in the peripheral region (not labeled) is greater than the thickness t2 of the cap layer 180 in the central region (not labeled), which can improve the effect of preventing unexpected flow of silicide. The aforementioned range of the thickness t2 may refer to a distance between the topmost surface of the second epitaxial layer 170 (i.e., the top surface 173) and the topmost surface of the cap layer 180 (i.e., the surface 181) in the vertical direction D2. The cap layer 180 completely covers the second epitaxial layer 170, and the side surface (not labeled) of the cap layer 180 may directly contact the second spacer 124.

The total thickness T1 of the second epitaxial layer 170 and the cap layer 180 (i.e., T1=t1+t2) in the direction perpendicular to the horizontal direction D1 is 130 angstroms to 350 angstroms. The thickness W1 of the sidewall (not label) of the second spacer 124 in the horizontal direction D1 is 150 angstroms to 200 angstroms. A ratio (T1/W1) of the total thickness T1 of the second epitaxial layer 170 and the cap layer 180 in the direction perpendicular to the horizontal direction D1 to the thickness W1 of the sidewall of the second spacer 124 in the horizontal direction D1 may be 1 to 2. Thereby, the effect of preventing unexpected flow of silicide can be improved.

Compared with the prior art, in the present disclosure, with the included angle between the surface of the second epitaxial layer and the horizontal direction falling within a specific range, it is beneficial to reduce the probability of forming voids in the side surfaces of the second epitaxial layer during the cleaning process without increasing the thickness of the cap layer. Thereby, it is beneficial to reduce the probability of short circuits between devices caused by excessively thick thickness of the cap layer, and can also reduce the probability of unexpected flow of silicide.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a gate structure disposed on a substrate;
a first epitaxial layer disposed in the substrate and at two sides of the gate structure;
a second epitaxial layer disposed on the first epitaxial layer, wherein an included angle between a surface of the second epitaxial layer and a horizontal direction is 15 degrees to 35 degrees; and
a cap layer disposed on the second epitaxial layer.

2. The semiconductor device of claim 1, wherein an included angle between a surface of the cap layer and the horizontal direction is 0 degrees to 5 degrees.

3. The semiconductor device of claim 2, wherein a material of the cap layer comprises silicon, and a crystal orientation of the surface of the cap layer is (100).

4. The semiconductor device of claim 1, wherein a thickness of the second epitaxial layer in a direction perpendicular to the horizontal direction is 30 angstroms to 150 angstroms.

5. The semiconductor device of claim 1, wherein a thickness of the cap layer in a direction perpendicular to the horizontal direction is 100 angstroms to 200 angstroms.

6. The semiconductor device of claim 1, wherein a total thickness of the second epitaxial layer and the cap layer in a direction perpendicular to the horizontal direction is 130 angstroms to 350 angstroms.

7. The semiconductor device of claim 1, further comprising:
a spacer surrounding the gate structure.

8. The semiconductor device of claim 7, wherein a ratio of a total thickness of the second epitaxial layer and the cap layer in a direction perpendicular to the horizontal direction to a thickness of a sidewall of the spacer in the horizontal direction is 1 to 2.

9. The semiconductor device of claim 7, wherein a thickness of a sidewall of the spacer in the horizontal direction is 150 angstroms to 200 angstroms.

10. The semiconductor device of claim 1, wherein a material of the second epitaxial layer comprises silicon germanium, and a crystal orientation of the surface of the second epitaxial layer is (311).

11. A method for fabricating a semiconductor device, comprising:
forming a gate structure on a substrate;
forming two recesses in the substrate and at two sides of the gate structure;
forming a first epitaxial layer in the two recesses;
forming a second epitaxial layer on the first epitaxial layer, wherein an included angle between a surface of the second epitaxial layer and a horizontal direction is 15 degrees to 35 degrees; and
forming a cap layer on the second epitaxial layer.

12. The method of claim 11, wherein an included angle between a surface of the cap layer and the horizontal direction is 0 degrees to 5 degrees.

13. The method of claim 11, wherein forming the second epitaxial layer and forming the cap layer comprise introducing an etching gas and a deposition material gas, and a molar ratio of the etching gas to the deposition material gas for forming the second epitaxial layer is greater than a molar ratio of the etching gas to the deposition material gas for forming the cap layer.

14. The method of claim 13, wherein the molar ratio of the etching gas to the deposition material gas for forming the second epitaxial layer is 1 to 2.

15. The method of claim 13, wherein the molar ratio of the etching gas to the deposition material gas for forming the cap layer is 0.45 to 0.55.

16. The method of claim 11, wherein a thickness of the second epitaxial layer in a direction perpendicular to the horizontal direction is 30 angstroms to 150 angstroms.

17. The method of claim 11, wherein a thickness of the cap layer in a direction perpendicular to the horizontal direction is 100 angstroms to 200 angstroms.

18. The method of claim 11, further comprising:
forming a spacer surrounding the gate structure.

19. The method of claim 18, wherein a ratio of a total thickness of the second epitaxial layer and the cap layer in a direction perpendicular to the horizontal direction to a thickness of a sidewall of the spacer in the horizontal direction is 1 to 2.

20. The method of claim 18, wherein a thickness of a sidewall of the spacer in the horizontal direction is 150 angstroms to 200 angstroms.
